(19) United States
(12) Patent Application Publication
(10) Pub. No.: US 2024/0107862 A1
(43) Pub. Date: Mar. 28, 2024

(54) DISPLAY DEVICE AND METHOD OF FABRICATING THE SAME

(71) Applicant: Samsung Display Co., LTD., Yongin-si (KR)

(72) Inventors: Eun Joong MUN, Yongin-si (KR); Shinya ONOUE, Yongin-si (KR); Jung Wook KIM, Yongin-si (KR); Hee Chang KIM, Yongin-si (KR); Kyoung Hee PARK, Yongin-si (KR); Ji Yun BANG, Yongin-si (KR)

(21) Appl. No.: 18/202,177

(22) Filed: May 25, 2023

(30) Foreign Application Priority Data
Sep. 23, 2022 (KR) 10-2022-0120938

(51) Int. Cl. H10K 59/80; H10K 59/12

(52) U.S. Cl. CPC H10K 59/8791; H10K 59/1201; H10K 59/8794

(57) ABSTRACT

There are provided a display device and a method of fabricating a display device. The display device includes: a substrate including a first surface and a second surface opposite to the first surface; a display element layer disposed on the first surface of the substrate, and a panel bottom member disposed on the second surface of the substrate. The panel bottom member includes: a light-blocking layer including a first base resin and light-blocking particles dispersed in the first base resin; a buffer layer including a second base resin; and a thermal protection member including a thermal protection material. A profile of the light-blocking layer conforms to a profile of the buffer layer in a plan view, and a surface of the light-blocking layer and a surface of the buffer layer are in direct contact with each other.

This application claims priority to Korean Patent Application No. 10-2022-0120938, filed on Sep. 23, 2022, and all the benefits accruing therefrom under 35 U.S.C. § 119, the content of which in its entirety is herein incorporated by reference.

### BACKGROUND

### 1. Field of the Disclosure

The present disclosure relates to a display device, and a method of fabricating the same.

### 2. Description of the Related Art

A display device becomes more and more important as multimedia technology evolves. Accordingly, a variety of types of display devices such as organic light-emitting display (“OLED”) devices and liquid-crystal display (“LCD”) devices are currently used.

The display device includes a display panel such as an organic light-emitting display panel and a liquid-crystal display panel for displaying images. Among them, light-emitting display panel may include light-emitting elements. For example, light-emitting diodes (“LEDs”) may include an organic light-emitting diode (OLED) using an organic material as a fluorescent material, and an inorganic light-emitting diode using an inorganic material as a fluorescent material.

In addition, the display device includes a panel bottom member disposed under a display panel. The panel bottom member may include a variety of functional sheets for protecting the display panel from heat, external impact, etc.

### SUMMARY

Aspects of the present disclosure provide a display device capable of reducing the thickness of a panel bottom member.

Aspects of the present disclosure also provide a method of fabricating a display device for reducing the thickness of a panel bottom member and easily forming a panel bottom member.

It should be noted that aspects of the present disclosure are not limited to the above-mentioned aspect; and other aspects of the present disclosure will be apparent to those skilled in the art from the following descriptions.

An embodiment of a display device includes: a substrate including a first surface and a second surface opposite to the first surface; a display element layer disposed on the first surface of the substrate; and a panel bottom member disposed on the second surface of the substrate, where the panel bottom member includes a light-blocking layer including a first base resin and light-blocking particles dispersed in the first base resin, a buffer layer including a second base resin, and a thermal protection member including a thermal protection material. A profile of the light-blocking layer conforms to a profile of the buffer layer when viewed from top (i.e., in a plan view), and a first surface of the light-blocking layer and a first surface of the buffer layer are in direct contact with each other.

A surface of the thermal protection member may be in direct contact with a second surface of the buffer layer, and the second surface of the buffer layer may be opposite to the first surface of the buffer layer.

The thermal protection member may include a third base resin; and nano-metal particles dispersed in the third base resin.

Each of the first base resin, the second base resin and the third base resin may be a solvent-free resin.

The nano-metal particles may include copper (Cu), and a diameter of each of the nano-metal particles may be equal to or less than 500 nm.

The thermal protection member may be disposed on a second surface of the buffer layer, and an adhesive member may be interposed between the second surface of the buffer layer and the thermal protection member.

The thermal protection member may include copper (Cu), and a profile of the thermal protection member may conform to a profile of the buffer layer when viewed from top.

The first surface of the light-blocking layer may form a first concave-convex pattern, and the first surface of the buffer layer may form a second concave-convex pattern engaged with the first concave-convex pattern.

The second surface of the substrate may be in direct contact with a second surface of the light-blocking layer, and the second surface of the light-blocking layer may be opposite to the first surface of the light-blocking layer.

The substrate may include one of glass and quartz.

The display device may further include: a lower film disposed directly on the second surface of the substrate, and the second surface of the light-blocking layer may be in direct contact with the lower film.

The substrate may include polyimide.

An embodiment of a display device includes: a substrate including a first surface and a second surface opposite to the first surface; and a display element layer disposed on the first surface of the substrate; and a panel bottom member disposed on the second surface of the substrate. The panel bottom member includes: a first base being a solvent-free resin; light-blocking particles dispersed in the first base; and a thermal protection material, and a profile of the panel bottom member conforms to a profile of the substrate when viewed from top (i.e., in a plan view).

The first base may include one of a thiol resin, an epoxy cation resin, and an amine resin.

A thickness of the first base may range from about 100 micrometers (μm) to about 120 μm.

The panel bottom member may further include nano-metal particles dispersed in the first base. the light-blocking particles may include carbon black, and the nano-metal particles may include copper (Cu) having a diameter of 500 nm or less.

The display device may further include a second base in direct contact with the first base. The second base may include one of a thiol resin, an epoxy cation resin and an amine resin, and the resins may be solvent-free resins.

A glass-transition temperature of the second base may be −30 degrees in Celsius (° C.) or less.

The thickness of the first base may be smaller than a thickness of the second base.

An embodiment of a method of fabricating a display device includes: forming a display element layer on a first surface of a substrate; applying a resin for a light-blocking layer on a second surface of the substrate opposite to the first surface; forming the light-blocking layer by curing the resin for the light-blocking layer applied on the second surface; applying a resin for a buffer layer directly on the light-blocking layer; and forming the buffer layer by curing the resin for the buffer layer applied directly on the light-blocking layer.

According to an embodiment of the present disclosure, it is possible to reduce the thickness of a panel bottom member of a display device.

According to an embodiment of the present disclosure, a method of fabricating a display device can reduce the thickness of a panel bottom member and can easily form the panel bottom member.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view showing a display device according to an embodiment of the present disclosure.

FIG. 2 is an exploded, perspective view of a display device according to an embodiment of the present disclosure.

FIG. 3 is a cross-sectional view schematically showing a cross section taken along line X1-X1′ of FIG. 1.

FIG. 4 is a side view showing an arrangement of a display panel and a panel bottom member of a display device according to an embodiment.

FIG. 5 is a cross-sectional view showing a stack structure of a display panel of a display device according to an embodiment of the present disclosure.

FIG. 6 is a cross-sectional view showing a structure of a panel bottom member of a display device according to an embodiment.

FIGS. 7 to 13 are views for illustrating the method of fabricating a display device according to an embodiment of the present disclosure.

FIG. 14 is a cross-sectional view showing a structure of a panel bottom member of a display device according to another embodiment.

FIG. 15 is a cross-sectional view showing a structure of a panel bottom member of a display device according to yet another embodiment.

FIG. 16 is a cross-sectional view showing a structure of a panel bottom member of a display device according to yet another embodiment.

FIG. 17 is a cross-sectional view showing a structure of a panel bottom member of a display device according to yet another embodiment.

FIG. 18 is a cross-sectional view showing a structure of a panel bottom member of a display device according to yet another embodiment.

FIG. 19 is a cross-sectional view showing an arrangement of a display panel and a panel bottom member of a display device according to yet another embodiment.

FIG. 20 is a cross-sectional view showing the stack structure of the display panel of the display device according to the embodiment of FIG. 19.

FIG. 21 is a cross-sectional view showing the structure of the panel bottom member of the display device according to the embodiment of FIG. 19.

### DETAILED DESCRIPTION

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art. The same reference numbers indicate the same components throughout the specification. In the attached figures, the thickness of layers and regions is exaggerated for clarity.

It will also be understood that when a layer is referred to as being “on” another layer or substrate, it can be directly on the other layer or substrate, or intervening layers may also be present. In contrast, when an element is referred to as being “directly on” another element, there are no intervening elements present. Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

Each of the various embodiments of the present invention may be partially or wholly capable of combining or combining with each other, technically various interlocking and driving are possible, and each embodiment may be able to be performed independently with respect to each other or may be implemented together in an association relationship.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value. Hereinafter, embodiments of the present disclosure will be described with reference to the accompanying drawings.

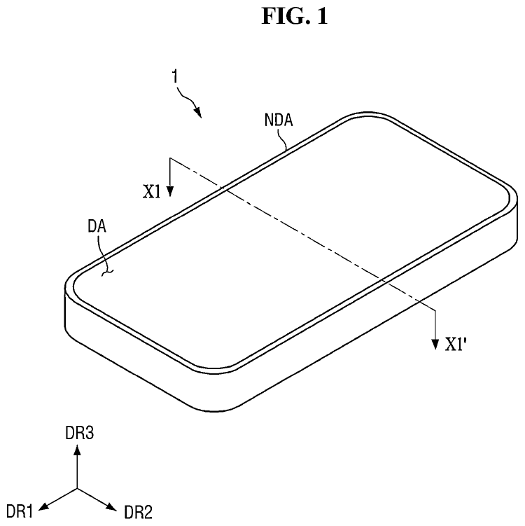

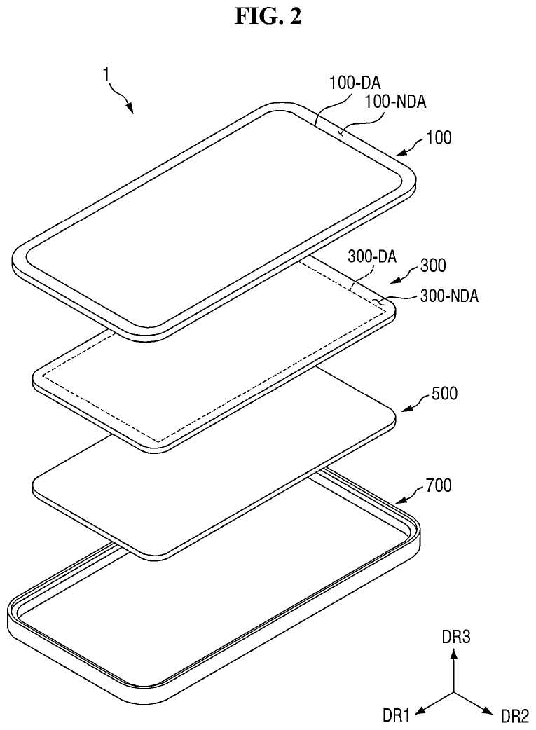

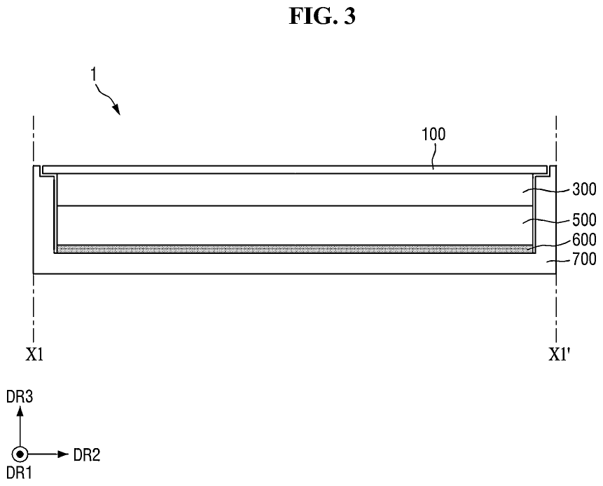

FIG. 1 is a perspective view showing a display device according to an embodiment of the present disclosure. FIG. 2 is an exploded, perspective view of a display device according to an embodiment of the present disclosure. FIG. 3 is a cross-sectional view schematically showing a cross section taken along line X1-X1′ of FIG. 1.

Referring to FIG. 1, the display device 1 displays a moving image or a still image. A display device 1 may refer to any electronic device that provides a display screen. For example, the display device 1 may include a television set, a laptop computer, a monitor, an electronic billboard, the Internet of Things devices, a mobile phone, a smart phone, a tablet personal computer (“PC”), an electronic watch, a smart watch, a watch phone, a head-mounted display device, a mobile communications terminal, an electronic notebook, an electronic book, a portable multimedia player (“PMP”), a navigation device, a game console and a digital camera, a camcorder, etc.

In FIG. 1, a first direction DR1, a second direction DR2 and a third direction DR3 are defined. The first direction DR1 and the second direction DR2 are perpendicular to each other, the first direction DR1 and the third direction DR3 are perpendicular to each other, and the second direction DR2 and the third direction DR3 may be perpendicular to each other. The first direction DR1 may refer to the vertical direction in the drawings, the second direction DR2 may refer to the horizontal direction in the drawings, and the third direction DR3 may refer to the up-and-down direction, i.e., the thickness direction of the display device 1 in the drawings. As used herein, a direction may refer to the direction indicated by the arrow as well as the opposite direction, unless specifically stated otherwise. If it is necessary to discern between such two opposite directions, one of the two directions may be referred to as “one side in the direction,” while the other direction may be referred to as “the opposite side in the direction”. In FIG. 1, the side indicated by an arrow indicative of a direction is referred to as one side in the direction, while the opposite side is referred to as the opposite side in the direction. As used herein, “when viewed from top” or “plan view” is a view in the opposite side in the third direction DR3.

In the following description of the surfaces of the display device 1 or the elements of the display device 1, the surfaces facing one side where images are displayed, i.e., the third direction DR3 will be referred to as the upper surface, while the opposite surfaces will be referred to as the lower surface for convenience of illustration. It should be understood, however, that the present disclosure is not limited thereto. The surfaces and the opposite surface of the elements may be referred to as a front surface and a rear surface, respectively, or may be referred to as a first surface and a second surface, respectively. In addition, in the description of relative positions of the elements of the display device 1, one side in the second direction DR2 may be referred to as the upper side while the opposite side in the third direction DR3 may be referred to as the lower side.

The shape of the display device 1 may be modified in a variety of ways. For example, the display device 1 may have shapes such as a rectangle with longer lateral sides, a rectangle with longer vertical sides, a square, a quadrangle with rounded corners (vertices), other polygons, a circle, etc. The shape of a display area DA of the display device 1 may also be similar to the overall shape of the display device 1. In the embodiment shown in FIG. 1, the display device 1 has a rectangular shape elongated in the first direction DR1, with the longer sides in the first direction DR1 and the shorter sides in the second direction DR2.

The display device 1 includes a display area DA for displaying an image, and a non-display area NDA adjacent to the display area DA. In the non-display area NDA, no image is displayed. The display area DPA may be referred to as an active area, while the non-display area NDA may also be referred to as an inactive area. The display area DA may generally occupy the center of the display device 1. In some embodiments, the non-display area NDA may surround the display area DA, but the present disclosure is not limited thereto.

Referring to FIGS. 2 and 3 in conjunction with FIG. 1, the display device 1 includes a display panel 300, and a panel bottom member 500 disposed under the display panel 300. The display device 1 may further include a window 100 disposed on the display panel 300. In addition, the display device 1 may further include a bracket 700 accommodating the display panel 300 and the panel bottom member 500 to form the exterior of the display device 1.

The window 100 includes a light-transmitting portion 100-DA for transmitting an image provided by the display panel 300, and a light-blocking portion 100-NDA adjacent to the light-transmitting portion 100-DA. In some embodiments, an opaque masking layer may be disposed the inner surface of the window 100 in the light-blocking portion 100-NDA.

The window 100 may be disposed on the display panel 300 to protect the display panel 300. The window 100 may be disposed to overlap the display panel 300 and cover the front surface of the display panel 300 in a plan view. The window 100 may be larger than the display panel 300. For example, the window 100 may protrude outwardly from the display panel 300 on the shorter sides of the display device 1, as shown in FIG. 3. The window 100 may protrude from the display panel 300 also at the longer sides of the display device 1. The window 100 may protrude more at the shorter sides than at the longer sides.

The window 100 may be made of glass, sapphire, plastic, or the like. The window 100 may be rigid, but the present disclosure is not limited thereto. The window 100 may be flexible.

The display panel 300 may be disposed under the window 100. The display panel 300 and the window 100 may be coupled with each other by a transparent coupling layer such as an optical clear adhesive (“OCA”) and an optical clear resin (“OCR”).

The display panel 300 includes a display area 300-DA and a non-display area 300-NDA. The display area 300-DA displays images and overlaps with the light-transmitting portion 100-DA of the window 100 in a plan view. The non-display area 300-NDA does not display images, is adjacent to the display area 300-DA, and overlaps with the light-blocking portion 100-NDA of the window 100 in a plan view. That is to say, the light-transmitting portion 100-DA of the window 100 and the display area 300-DA of the display panel 300 may define the display area DA of the display device 1, and the light-blocking portion 100-NDA of the window 100 and the non-display area 300-NDA of the display panel 300 may define the non-display area NDA of the display device 1.

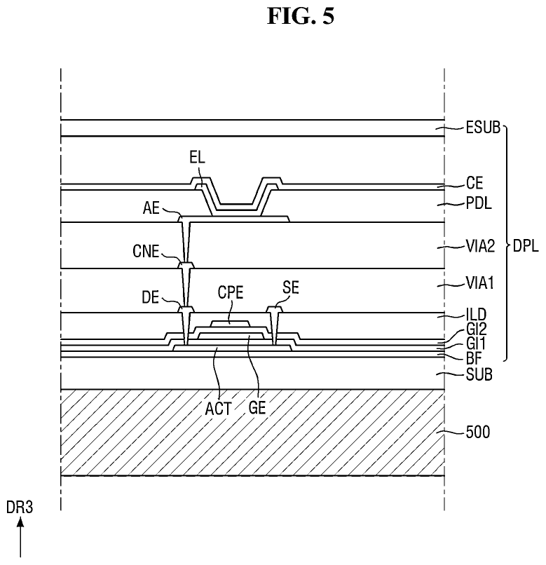

In some embodiments, the display panel 300 may include a self-luminous element. In an embodiment, the self-luminous element may include at least one of an organic light-emitting diode, a quantum dot light-emitting diode, and a micro light-emitting diode based on inorganic material (e.g., Micro LED). In the following description, it is assumed that the self-luminous element is an organic light-emitting element for convenience of illustration. A detailed description of each of the elements of the display panel 300 will be described later with reference to FIG. 5.

The panel bottom member 500 is disposed under the display panel 300. The panel bottom member 500 may be coupled with the display panel 300 without any adhesive member. In addition, the panel bottom member 500 may have substantially the same profile as the display panel 300 when viewed from the top (i.e., in a plan view) and may overlap with the display panel 300. The side surfaces of the panel bottom member 500 may be aligned with the side surfaces of the display panel 300. This may be because the panel bottom member 500 is made of a resin. This will be described in more detail later.

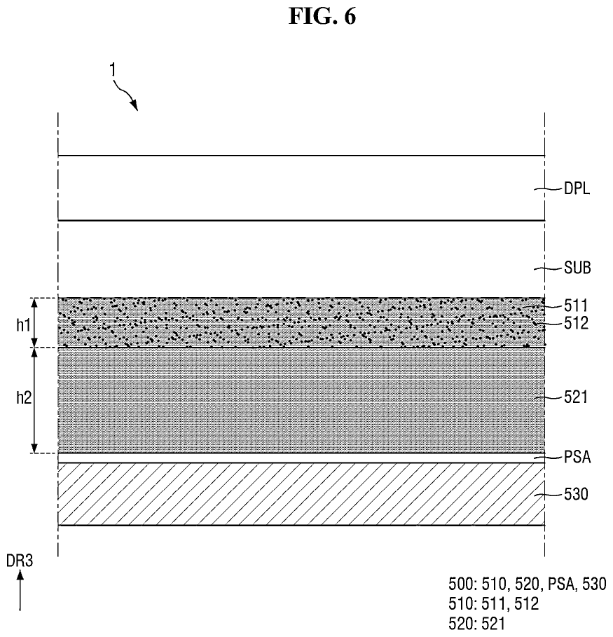

The panel bottom member 500 can protect against heat, block electromagnetic waves, block or absorb light, absorb shock, and so on. The panel bottom member 500 may include a functional layer having at least one of the above-described functions. The structure of the panel bottom member 500 will be described in detail later with reference to FIG. 6.

The bracket 700 may be located under the panel bottom member 500. The bracket 700 supports the window 100, the display panel 300, and the panel bottom member 500. The bracket 700 may include a bottom and side walls. The bottom of the bracket 700 may face the lower surface of the panel bottom member 500, and the side walls of the bracket 700 may face the side surfaces of the window 100, the display panel 300 and the panel bottom member 500. The bracket 700 may be made of a synthetic resin material, a metal material, or a combination of different materials.

A bottom buffer member 600 may be interposed between the lower surface of the panel bottom member 500 and the bottom of the bracket 700. The bottom buffer member 600 absorbs an external shock to prevent the display device 1 from being damaged. The bottom buffer member 600 may include an elastic material such as a rubber and a sponge formed by foaming a urethane-based material or an acrylic-based material.

Hereinafter, the structure of the display panel 300 and the panel bottom cover 500 of the display device 1 according to the embodiment of the present disclosure will be described in detail.

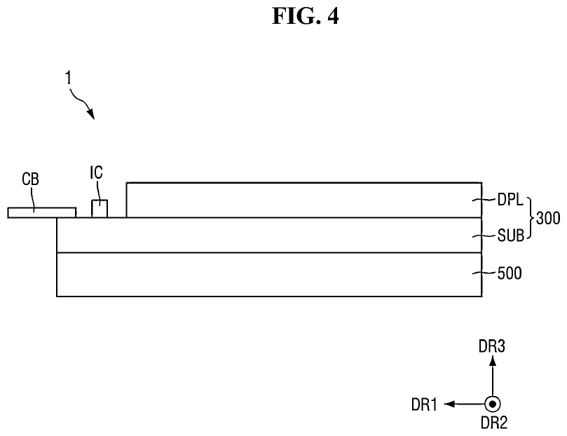

FIG. 4 is a side view showing an arrangement of a display panel and a panel bottom member of a display device according to an embodiment.

Referring to FIG. 4, the display panel 300 of the display device 1 according to the embodiment may include a display substrate SUB and a display element layer DPL disposed on the upper surface of the display substrate SUB, and the panel bottom member 500 may be disposed on the lower surface of the display substrate SUB of the display panel 300.

In some embodiments, the display substrate SUB may include, but is not limited to, glass, quartz or the like as a rigid material. In the embodiment shown in FIGS. 4 to 6, the display substrate SUB includes glass or quartz as a rigid material.

The display substrate SUB may include a subsidiary area SA in which a driver circuit IC and a circuit board CB are mounted, and a main area MA in which the display element layer DPL is disposed.

The panel bottom member 500 may be disposed on the lower surface of the display substrate SUB and may have substantially the same profile as the display substrate SUB when viewed from the top. For example, the panel bottom member 500 may be extended not only to the main area MA of the display substrate SUB but also to the subsidiary area SA to cover the lower surface of the substrate SUB.

The driver circuit IC and the circuit board CB mounted in the subsidiary area SA of the display substrate SUB may output signals and voltages for driving the display element layer DPL of the display panel 300.

The driver circuit IC may be implemented as an integrated circuit (“IC”) and may be attached on the display panel 300 by a chip-on-glass (“COG”) technique, a chip-on-plastic (“COP”) technique, or ultrasonic bonding. In addition, the circuit board CB may be attached on the display panel 300 using an anisotropic conductive film (“ACF”). The circuit board CB may be a flexible printed circuit board (“FPCB”), a printed circuit board (“PCB”), or a flexible film such as a chip-on-film (“COF”).

The display element layer DPL disposed in the main area MA of the display substrate SUB may include light-emitting elements to display images. Hereinafter, various elements forming the display element layer DPL will be roughly described with reference to FIG. 5.

FIG. 5 is a cross-sectional view showing a stack structure of a display panel of a display device according to an embodiment of the present disclosure.

As described above, the display substrate SUB may include glass, quartz or the like as a rigid material.

A buffer layer BF may be disposed on the display substrate SUB. The buffer layer BF may include an inorganic film that can prevent the permeation of air or moisture. For example, the buffer layer BF may include a plurality of inorganic films stacked on one another alternately.

The thin-film transistor may be disposed on the buffer layer BF, and may form a pixel circuit of each of a plurality of pixels. For example, the thin-film transistor may be a driving transistor or a switching transistor of the pixel circuits. The thin-film transistor may include a semiconductor layer ACT, a source electrode SE, a drain electrode DE and a gate electrode GE.

The semiconductor layer ACT may be disposed on the buffer layer BF. The semiconductor layer ACT may overlap the gate electrode GE in the thickness direction (i.e., the third direction DR3) and may be insulated from the gate electrode GE by a first gate insulator GI1.

The first gate insulator GI1 may be disposed on the semiconductor layer ACT. For example, the first gate insulator GI1 may cover the semiconductor layer ACT and the buffer layer BF, and may insulate the semiconductor layer ACT from the gate electrode GE disposed thereon. The first gate insulator GI1 may include contact holes through which the source electrode SE and the drain electrode DE pass.

The gate electrode GE may be disposed on the first gate insulator GI1. The gate electrode GE may overlap the semiconductor layer ACT with the first gate insulator GI1 therebetween in a plan view.

A second gate insulator GI2 may cover the gate electrode GE and the first gate insulator GI1. The second gate insulator GI2 may include contact holes through which the source electrode SE and the drain electrode DE pass. The contact holes of the second gate insulator GI2 may be connected to contact holes of the gate insulator GI and the contact holes of the interlayer dielectric layer ILD, which will be described later.

A capacitor electrode CPE may be disposed on the second gate insulator GI2. The capacitor electrode CPE may overlap with the gate electrode GE in the third direction DR3 (i.e., thickness direction). The capacitor electrode CPE and the gate electrode GE may form a capacitance.

The interlayer dielectric layer ILD may cover the capacitor electrode CPE and the second gate insulator GI2. The interlayer dielectric layer ILD may include contact holes through which the source electrode SE and the drain electrode DE pass. The contact holes of the interlayer dielectric layer ILD may be connected to the contact holes of the gate insulator GI and the contact holes of the second gate insulator GI2.

The source electrode SE and the drain electrode DE may be disposed on the interlayer dielectric layer ILD. The source electrode SE and the drain electrode DE may be electrically connected to the semiconductor layer ACT of the thin-film transistor. For example, the source electrode SE and the drain electrode DE may be inserted into the contact holes formed in the interlayer dielectric layer ILD, the first gate insulator GI1 and the second gate insulator GI2, and may be in contact with the semiconductor layer ACT of the thin-film transistor.

A first via insulating layer VIA1 may cover the source electrode SE, the drain electrode DE and the interlayer dielectric layer ILD. The first via insulating layer VIA1 can protect the thin-film transistor. The first via insulating layer VIA1 may include a contact hole through which the connection electrode CNE passes.

The connection electrode CNE may be disposed on the first via insulating layer VIA1. The connection electrode CNE may electrically connect a pixel electrode AE of a light-emitting element ED to be described later with the drain electrode DE of the thin-film transistor. The connection electrode CNE may be inserted into a contact hole formed in the first via insulating layer VIA1 to be in contact with the drain electrode DE.

A second via insulating layer VIA2 may cover the connection electrode CNE and the first via insulating layer VIA1. The second via insulating layer VIA2 may include a contact hole through which the pixel electrode AE of the light-emitting element passes.

The light-emitting element may include a pixel electrode AE, an emissive layer EL, and a common electrode CE.

The pixel electrode AE may be disposed on the second via insulating layer VIA2. The pixel electrode AE may be disposed in line with an opening of a pixel-defining layer PDL. The pixel electrode AE may be electrically connected to the drain electrode DE of the thin-film transistor through the connection electrode CNE.

The pixel-defining layer PDL including the opening may be disposed on the second via insulating layer VIA2 and a part of the pixel electrode AE. The opening of the pixel-defining layer PDL may expose a part of the pixel electrode AE.

The pixel-defining layer PDL may separate and insulate the pixel electrodes AE of the plurality of light-emitting elements from one another. The pixel-defining layer PDL may include a light-absorbing material to prevent light reflection. For example, the pixel-defining layer PDL may include a polyimide (“PI”)-based binder, and pigments in which red, green and blue are mixed. Alternatively, the pixel-defining layer PDL may include a cardo-based binder resin and a mixture of lactam black pigment and blue pigment. Alternatively, the pixel-defining layer PDL may include carbon black.

The emissive layer EL may be disposed on a part of the pixel electrode AE and the pixel-defining layer PDL. For example, the emissive layer EL may be disposed on a part of one surface of the pixel electrode AE exposed by the opening formed by the pixel-defining layer PDL and a part of the pixel-defining layer PDL.

The emissive layer EL may be an organic emissive layer made of an organic material. If the emissive layer EL is an organic emissive layer, when the thin-film transistor applies a predetermined voltage to the pixel electrode AE of the light-emitting element and the common electrode CE of the light-emitting element receives a common voltage or cathode voltage, the holes and electrons may move to the emissive layer EL through a hole transporting layer and an electron transporting layer, respectively, and they combine in the emissive layer EL to emit light.

The common electrode CE may be disposed on the emissive layer EL and the pixel-defining layer PDL. For example, the common electrode CE may be disposed on the emissive layer EL and a part of the pixel-defining layer PDL on which the emissive layer EL is not disposed. In addition, the common electrode CE may be extended throughout the front surface of the display area DA in the form of an electrode common to all pixels without being disposed separately in a plurality of pixels.

The common electrode CE may receive a common voltage or a low-level voltage. When the pixel electrode AE receives the voltage equal to the data voltage and the common electrode CAT receives the low-level voltage, a potential difference is formed between the pixel electrode AE and the common electrode CE, so that the emissive layer EL can emit light.

An encapsulation substrate ESUB may be disposed above the common electrode CE such that it is spaced apart from the common electrode CE in the third direction DR3. The encapsulation substrate ESUB can protect a variety of elements disposed thereunder by isolating them from the outside. The encapsulation substrate ESUB may be made of a rigid material, and may include, but is not limited to, glass or quartz. In some embodiments, a separate filler may be interposed in the space between the encapsulation substrate ESUB and the common electrode CE.

FIG. 6 is a cross-sectional view showing a structure of a panel bottom member of a display device according to an embodiment.

The structure of the panel bottom member 500 disposed on the lower surface of the display substrate SUB will be described with reference to FIG. 6. The panel bottom member 500 may include a light-blocking layer 510, a buffer layer 520 and a thermal protection member 530.

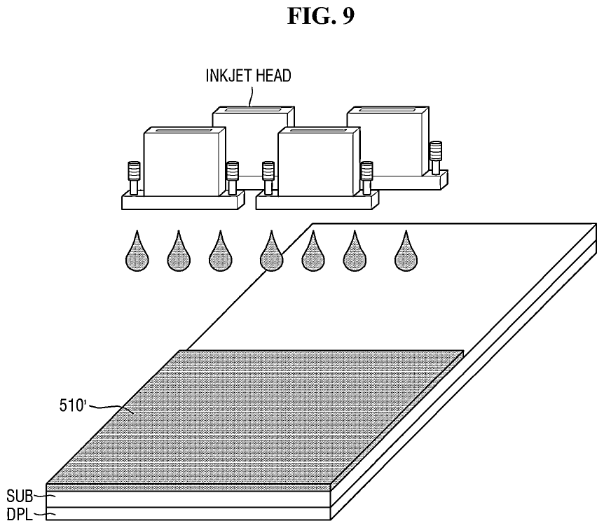

The light-blocking layer 510 may be disposed under the display substrate SUB to block transmission of light and to prevent the elements disposed under the light-blocking layer 510 from being seen from the outside of the display device 1. In some embodiments, the light-blocking layer 510 may be in direct contact with the lower surface of the display substrate SUB, and the profile of the light-blocking layer 510 may be substantially identical to the profile of the display substrate SUB when viewed from the top (i.e., in a plan view). For example, the entirely lower surface of the light-blocking layer 510 may be in direct contact with the entire lower surface of the display substrate SUB. This is achieved by applying a resin 510′ for a light-blocking layer (see FIG. 9) directly on the lower surface of the display substrate SUB and then curing it to form the light-blocking layer 510 during the process of fabricating the display device to be described later, which is coated on the lower surface of the display substrate SUB. This will be described in more detail later.

The light-blocking layer 510 may include a first base resin 511 and light-blocking particles 512 dispersed in the first base resin 511.

The first base resin 511 may be a solvent-free resin. As used herein, a solvent-free resin refers to a resin that does not contain or hardly contains an organic solvent such as a thinner, in which the content of the organic solvent is less than 5%.

Typically, a resin contains an organic solvent. When the resin is cured, it is cured from the surface, meanwhile, the organic solvent is evaporated. If a resin having a high content of an organic solvent is cured to a thickness of several micrometers (μm), the organic solvent is trapped by the cured surface and cannot be evaporated. As a result, there may be a defect that the resin under the surface cannot be cured.

In order for the light-blocking layer 510 under the display substrate SUB to block transmission of light, it is desirable to have a thickness of approximately 20 μm or more. When the light-blocking layer 510 is formed of or includes the first base resin 511 which is a solvent-free resin, the light-blocking layer 510 can be formed via an inkjet printing process as in the method of fabricating a display device to be described later. Therefore, no adhesive member is required, and thus the fabricating process can become simpler, and the thickness desirable for the light-blocking layer 510 can be obtained.

In some embodiments, the first base resin 511 may include a solvent-free thiol resin, an epoxy cation resin, or an amine resin. This may be to prevent deterioration of the surface curing reaction due to oxygen present in the atmosphere as the light-blocking layer 510 is formed in the atmosphere. A detailed description thereon will be made later.

In some embodiments, the light-blocking particles 512 may include, but are not limited to, carbon black particles. The light-blocking particles 512 may have a diameter of approximately several nanometers (nm).

In some embodiments, the thickness h1 of the light-blocking layer 510 may be, but is not limited to, approximately 20 μm to 36 μm in the thickness direction (i.e., third direction DR3).

The buffer layer 520 can absorb an external shock to prevent the display panel 300, the window 100 and the like from being damaged. In some embodiments, the buffer layer 520 may be disposed under the light-blocking layer 510, and the lower surface of the light-blocking layer 510 and the upper surface of the buffer layer 520 may be in direct contact with each other. It should be understood, however, that the present disclosure is not limited thereto. For example, the buffer layer 520 may be disposed under the light-blocking layer 510. In the embodiment shown in FIG. 6, the buffer layer 520 may be disposed under the light-blocking layer 510, and the lower surface of the light-blocking layer 510 and the upper surface of the buffer layer 520 may be in direct contact with each other.

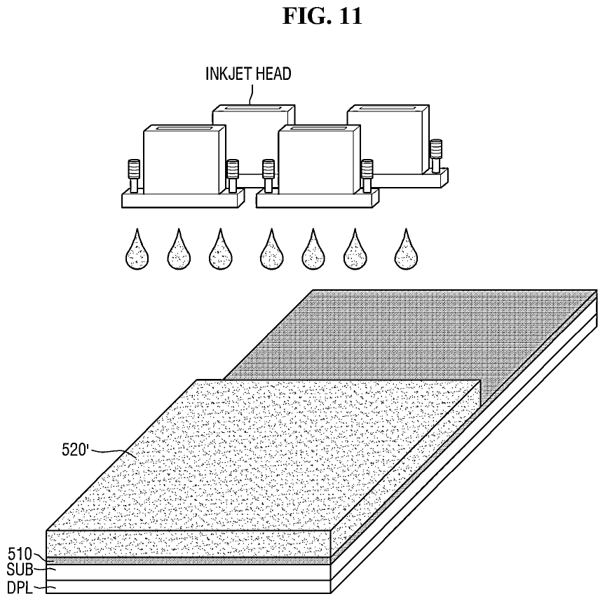

In this instance, the buffer layer 520 may be in direct contact with the lower surface of the light-blocking layer 510, and the profile of the buffer layer 520 may be substantially identical to the profile of the light-blocking layer 510 when viewed from the top. For example, the entire lower surface of the buffer layer 520 may be in direct contact with the entire lower surface of the light-blocking layer 510. This is achieved by applying a resin 520′ for a buffer layer (see FIG. 11) directly on the lower surface of the light-blocking layer 510 and then curing it to form the buffer layer 520 during the process of fabricating the display device to be described later, which is coated on the lower surface of the light-blocking layer 510. This will be described in more detail later.

The buffer layer 520 may be formed of or include a second base resin 521. The second base resin 521 may be a solvent-free resin. When the buffer layer 520 is made of a resin, the buffer layer 520 is desirable to have a thickness of approximately 100 μm or more in order to absorb an external shock. Therefore, as described above, in order to form the buffer layer 520 with a thickness of several micrometers (μm), the second base resin 521 should be a solvent-free type resin. In some embodiments, the second base resin 521 of the buffer layer 520 and the first base resin 511 of the light-blocking layer 510 may have different compositions, but the present disclosure is not limited thereto. For example, the second base resin 521 of the buffer layer 520 and the first base resin 511 of the light-blocking layer 510 may be resins having the same composition.

The second base resin 521 may have a glass-transition temperature of −30 degrees in Celsius (° C.) or less. The glass-transition temperature refers to the temperature at which a material transitions from a hard and relatively brittle glassy state to a viscous or rubbery state as the temperature rises, which is a reversible phase transition that affects the amorphous part of the material. Typically, the lower the glass-transition temperature of a resin is, the better the impact of the resin can be. For example, if the glass-transition temperature is high, it may be broken by a relatively weak impact, whereas if the glass-transition temperature is low, it may not be broken even by a relatively strong impact. If the glass-transition temperature of the second base resin 521 is −30° C. or less, the impact resistance desirable for the buffer layer 520 can be ensured. If the glass-transition temperature of the second base resin 521 is higher than −30° C., the impact resistance desirable for the buffer layer 520 may not be ensured. For example, if the glass-transition temperature of the second base resin 521 is −42.9° C., the second base resin 521 may not be broken even though an iron ball is dropped from the height of 13 centimeters (cm) onto the second base resin 521.

In some embodiments, the second base resin 521 may include a solvent-free thiol resin, an epoxy cation resin, or an amine resin. This may be to prevent deterioration of the surface curing reaction due to oxygen present in the atmosphere as the buffer layer 520 is formed in the atmosphere. A detailed description thereon will be made later.

In some embodiments, the thickness h2 of the buffer layer 520 may be, but is not limited to, approximately 100 μm to 120 μm. The thickness h2 of the buffer layer 520 may be greater than the thickness h1 of light-blocking layer 510.

The thermal protection member 530 can prevent outside heat from entering the display panel 300, and can block an electric wave generated from the display panel 300. The thermal protection member 530 may include graphite, copper (Cu), nickel (Ni), silver (Ag), etc., which can protect against heat effectively (hereinafter “thermal protection material”).

In some embodiments, the thermal protection member 530 may be disposed under the buffer layer 520, but the present disclosure is not limited thereto. For example, the thermal protection member 530 may be disposed on the buffer layer 520. The thermal protection member 530 may be attached to the lower surface of the buffer layer 520 by an adhesive member PSA. The thickness of the adhesive member PSA may be approximately 20 μm.

With the above configuration, the light-blocking layer 510 and the buffer layer 520 of the panel bottom member 500 can be attached without any adhesive member therebetween, so that the process can become simplified. In addition, the thickness of the panel bottom member 500 can be effectively reduced by the thickness of the eliminated adhesive member. Hereinafter, a method of fabricating the display device 1 according to the embodiment of the present disclosure will be described.

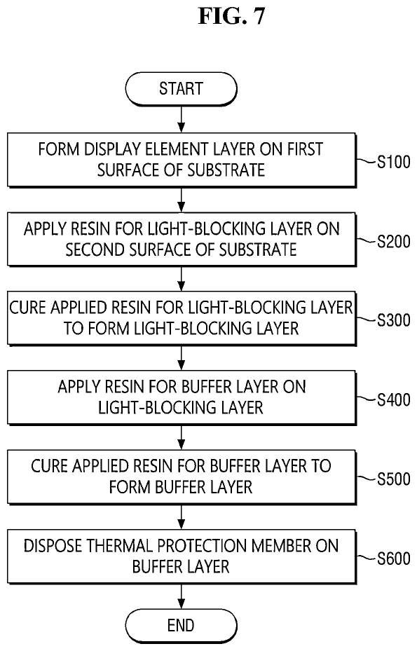

FIGS. 7 to 13 are views for illustrating a method of fabricating a display device according to an embodiment of the present disclosure.

Referring to FIG. 7, the method of fabricating the display device 1 may include forming: a display element layer DPL on a first surface (e.g., upper surface) of a display substrate SUB (step S100); applying a resin 510′ for a light-blocking layer on a second surface (e.g., lower surface) of the display substrate SUB (step S200); forming a light-blocking layer 510 by curing the applied resin 510′ (step S300); applying a resin 520′ for a buffer layer on the light-blocking layer 510 (step S400); forming a buffer layer 520 by curing the applied resin 520′ (step S500); and disposing a thermal protection member 530 on the buffer layer 520 (step S600).

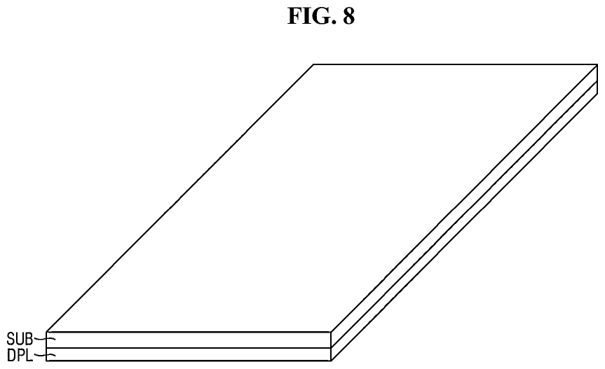

Initially, referring to FIG. 8, a display element layer DPL is formed on a first surface of a display substrate SUB (step S100). A method of forming the display element layer DPL is well known in the art, and thus a detailed description thereof will be omitted.

The process of forming the display element layer DPL may be carried out every mother substrate or every cell. The display substrate SUB may be a part of the mother substrate, and the mother substrate may be scribed into cells after the process of forming the display element layer DPL.

Subsequently, the display substrate SUB may be turned over so that the lower surface, i.e., a second surface of the display substrate SUB faces the upper side. In this instance, the window 100 (see FIG. 2) may be attached on the display element layer DPL. In FIGS. 8 to 13, the window 100 is not depicted for convenience of illustration. After the mother substrate is scribed into cells to form the display substrate SUB, the process of forming the panel bottom member 500 on the display substrate SUB may be carried out while being exposed to the atmosphere.

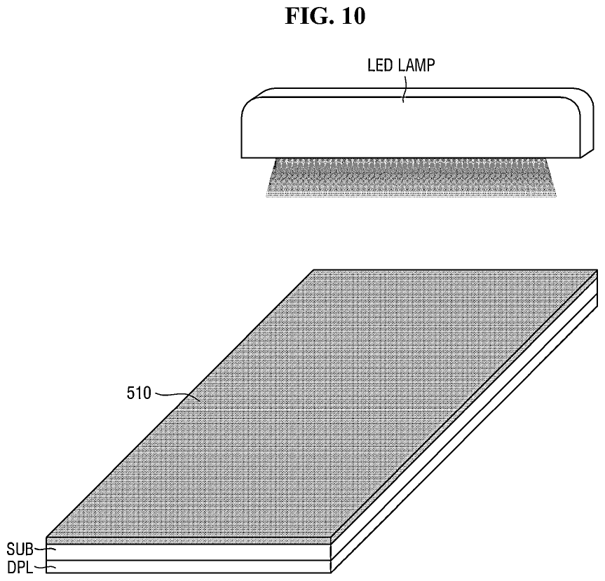

Subsequently, referring to FIG. 9 in conjunction with FIG. 10, a resin 510′ for a light-blocking layer is applied on the second surface of the display substrate SUB (step S200). The process of applying the resin 510′ for the light-blocking layer may be carried out, for example, via an inkjet printing process using an inkjet head.

The resin 510′ for the light-blocking layer may include a first base resin 511 (see FIG. 6) and light-blocking particles 512 (see FIG. 6) dispersed in the first base resin 511. The resin 510′ may be in a liquid state before the first base resin 511 is cured. Accordingly, the resin 510′ may be discharged from the inkjet head and applied on the second surface of the substrate SUB.

As shown in FIG. 10, the resin 510′ is applied via an inkjet printing process, and may be formed to have a uniform thickness with the profile substantially identical to the profile of the substrate SUB when viewed from the top (i.e., in a plan view). In addition, as the resin 510′ is applied via the inkjet printing process, a constant pattern can be easily formed by adjusting the discharge amount of the inkjet head.

The resin 510′ may be a solvent-free resin. Accordingly, the resin 510′ may be applied with a thickness of several micrometers (μm). In some embodiments, the resin 510′ may be applied with a thickness of 20 μm to 36 μm, but the present disclosure is not limited thereto. For example, the resin 510′ may have a thickness greater than 36 μm. If the resin 510′ has a thickness of less than 20 μm, the light-blocking layer 510 may not have sufficient light-blocking properties. If the resin 510′ has a thickness of greater than 36 μm, the center portion may not be properly cured due to the light-blocking particles 512. Accordingly, by applying the resin 510′ with a thickness of 20 μm to 36 μm, light can be blocked reliably and it can be cured stably.

The resin 510′ may have a viscosity of approximately 10 centipoise (cP) or less at the moment it is discharged from the inkjet head. Accordingly, the resin 510′ may be easily discharged from the inkjet head. On the other hand, viscosity is generally inversely proportional to temperature, and thus it is necessary to ensure an appropriate temperature in order to achieve a viscosity of 10 cP or less. Since the resin 510′ has a viscosity of 10 cP or less at a temperature of approximately 50° C. or higher, the process of discharging the resin 510′ may be carried out at a temperature of approximately 50° C. or higher.

Subsequently, referring to FIG. 10 in conjunction with FIG. 9, after the resin 510′ has been applied, the resin 510′ is cured to form the light-blocking layer 510 (step S300). The process of curing the resin 510′ may be carried out using, for example, ultraviolet rays.

The resin 510′ may be applied and cured as it is exposed to the atmosphere as described above. Accordingly, when a typical resin, for example, polyurethane, polycarbonate, polypropylene, polyethylene, etc. is used as the resin 510′, it may react with oxygen in the atmosphere. As a result, the surface may not be sufficiently cured. For this reason, a thiol-based resin, an epoxy cation resin, or an amine resin that does not react with oxygen in the atmosphere is used as the resin 510′, so that the surface can be cured easily.

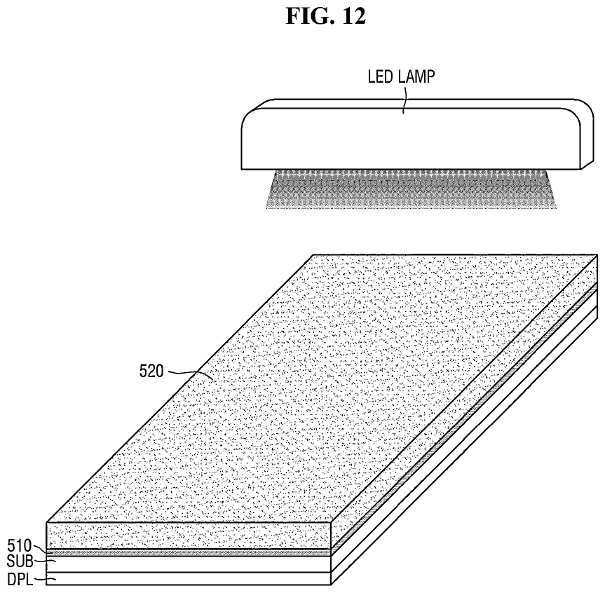

Subsequently, referring to FIG. 11 in conjunction with FIG. 12, a resin 520′ for a buffer layer is applied on the light-blocking layer 510 (step S400). The process of applying the resin 520′ for the buffer layer may be carried out, for example, via an inkjet printing process using an inkjet head.

The resin 520′ may include a second base resin 521 (see FIG. 6). The resin 520′ may be in a liquid state before the second base resin 521 is cured. Accordingly, the resin 520′ may be discharged from the inkjet head and applied on the lower surface of the light-blocking layer 510.

As shown in FIG. 12, the resin 520′ is applied via an inkjet printing process, and may be formed to have a uniform thickness with the profile substantially identical to the profile of the substrate SUB and the profile of the light-blocking layer 510 when viewed from the top. In addition, as the resin 520′ is applied via the inkjet printing process, a constant pattern can be easily formed by adjusting the discharge amount of the inkjet head.

The resin 520′ may be a solvent-free resin. Accordingly, the resin 520′ may be applied with a thickness of several micrometers (μm). In some embodiments, the resin 520′ may have, but is not limited to, a range of 100 μm to 120 μm. If the thickness of the resin 520′ is less than 100 μm, the impact resistance desirable for the buffer layer 520 may not be sufficient. If the thickness is greater than 120 μm, the panel bottom member 500 may be too thick. Accordingly, by applying the resin 520′ with a thickness of 100 μm to 120 μm, it is possible to achieve the impact resistance desirable for the buffer layer 520 and to reduce the thickness of the panel bottom member 500.

The resin 520′ may have a viscosity of approximately 10 cP or less at the moment it is discharged from the inkjet head. Accordingly, the resin 520′ may be easily discharged from the inkjet head. On the other hand, viscosity is generally inversely proportional to temperature, and thus it is necessary to ensure an appropriate temperature in order to achieve a viscosity of 10 cP or less. Since the resin 520′ has a viscosity of 10 cP or less at a temperature of approximately 50° C. or higher, the process of discharging the resin 520′ may be carried out at a temperature of approximately 50° C. or higher.

Subsequently, referring to FIG. 12 in conjunction with FIG. 11, after the resin 520′ has been applied, the resin 520′ is cured to form the buffer layer 520 (step S500). The process of curing the resin 520′ may be carried out using, for example, ultraviolet rays.

The resin 520′ may be applied and cured as it is exposed to the atmosphere as described above. Accordingly, when a typical resin, for example, polyurethane, polycarbonate, polypropylene, polyethylene, etc. is used as the resin 520′, it may react with oxygen in the atmosphere. As a result, the surface may not be sufficiently cured. For this reason, a thiol resin, an epoxy cation resin, or an amine resin that does not react with oxygen in the atmosphere is used as the resin 520′, so that the surface can be cured easily.

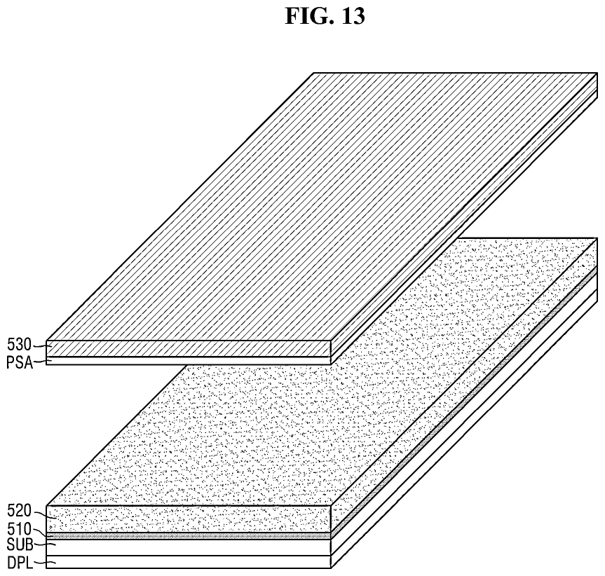

Lastly, referring to FIG. 13, a thermal protection member 530 is mounted on the buffer layer 520 (step S600). The thermal protection member 530 may be attached to the lower surface of the buffer layer 520 via an adhesive member PSA.

Hereinafter, display device according to other embodiments of the present disclosure will be described. In the following description, the same or similar elements will be denoted by the same or similar reference numerals, and redundant descriptions will be omitted or briefly described.

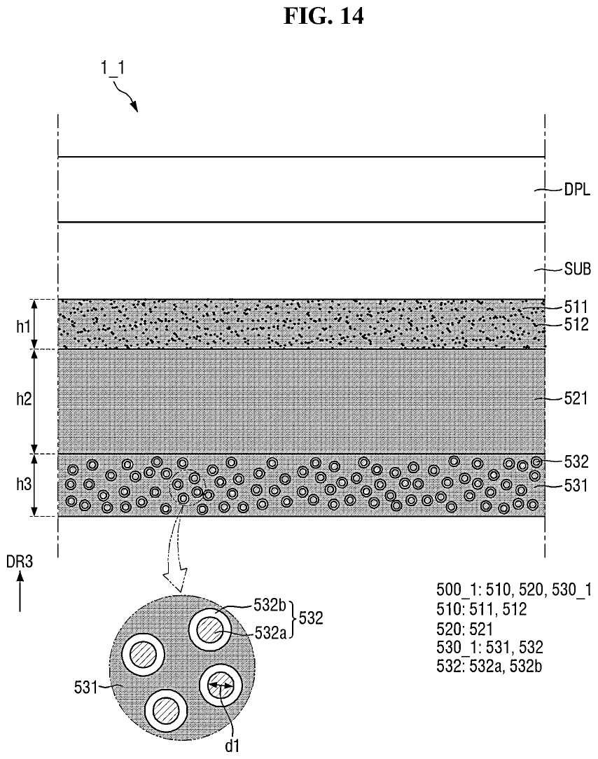

FIG. 14 is a cross-sectional view showing a structure of a panel bottom member of a display device according to another embodiment.

In the embodiment shown in FIG. 14, a thermal protection member 530_1 of a panel bottom member 500_1 is formed of or includes a resin in a display device 11, so that it can be attached to the lower surface of a buffer layer 520 without any adhesive member therebetween. For example, the thermal protection member 530_1 may include a third base resin 531 and nano-metal particles 532 dispersed in the third base resin 531.

In this instance, the thermal protection member 530_1 may be in direct contact with the lower surface of the buffer layer 520, and the profile of the thermal protection member 530_1 may be substantially identical to the profile of the buffer layer 520 when viewed from the top (i.e., in a plan view). For example, the entire upper surface of the thermal protection member 530_1 may be in direct contact with the entire lower surface of the buffer layer 520. This is achieved by applying a resin for a thermal protection member directly on the lower surface of the buffer layer 520 and then curing the resin to form the thermal protection member 530_1 during the process of fabricating the display device, which is coated on the lower surface of the buffer layer 520.

The thermal protection member 530_1 may include a third base resin 531 and nano-metal particles 532 dispersed in the third base resin 531.

The third base resin 531 of the thermal protection member 530_1 may be a solvent-free resin. When the thermal protection member 530_1 is made of a resin, the thickness should be approximately 40 μm or more in order to protect against heat. Therefore, as described above, in order to form the thermal protection member 530_1 with a thickness of several ten micrometers (μm), the third base resin 531 should be a solvent-free type resin. In some embodiments, the third base resin 531 of the thermal protection member 530_1, the second base resin 521 of the buffer layer 520 and the first base resin 511 of the light-blocking layer 510 may have different compositions from each other, but the present disclosure is not limited thereto. For another example, the third base resin 531 of the thermal protection member 530_1, the second base resin 521 of the buffer layer 520 and the first base resin 511 of the light-blocking layer 510 may have the same composition.

In some embodiments, the third base resin 531 may include a solvent-free thiol resin, an epoxy cation resin, or an amine resin. This may be to prevent deterioration of the surface curing reaction due to oxygen present in the atmosphere as the thermal protection member 530_1 is formed in the atmosphere.

Each of the nano-metal particles 532 of the thermal protection member 530_1 may include a metal core 532a and a shell 532b surrounding the metal core 532a. The metal core 532a may include copper (Cu), nickel (Ni), silver (Ag), or the like, which can effectively protect against heat, and the shell 532b may include an organic material. In some embodiments, the diameter dl of the metal core 532a may be greater than 0 nm and equal to or less than 500 nm. In some embodiments, the diameter dl of the metal core 532a may be but not limited to, approximately 200 nm. In some embodiments, a diameter of each of the nano-metal particles 532 may be greater than 0 nm and equal to or less than 500 nm.

In some embodiments, the thickness h3 of the thermal protection member 530_1 may have, but is not limited to, a range of 40 μm to 50 μm in the thickness direction (i.e., third direction DR3).

With the above configuration, the panel bottom member 500_1 according to this embodiment requires no adhesive member between the thermal protection member 530_1 and the buffer layer 520, so that the thickness of the panel bottom member 500_1 can be effectively reduced.

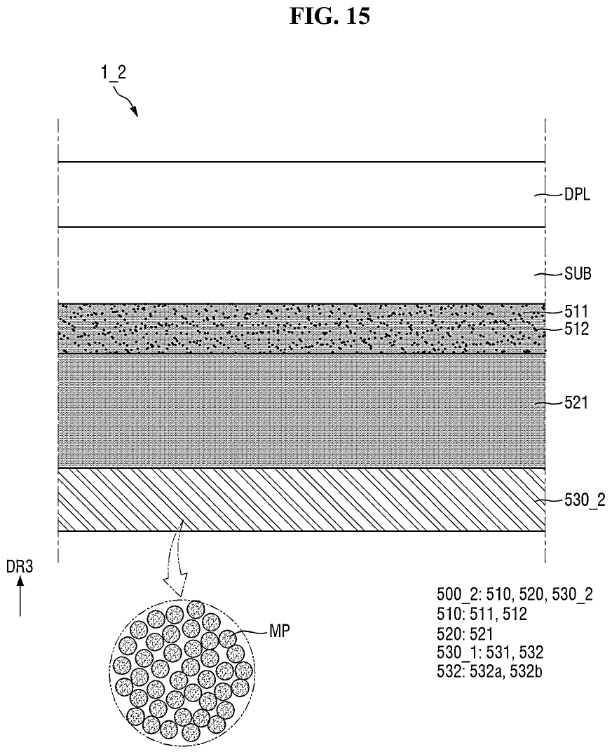

FIG. 15 is a cross-sectional view showing a structure of a panel bottom member of a display device according to yet another embodiment.

In the embodiment shown in FIG. 15, a thermal protection member 530_2 of a panel bottom member 500_2 in a display device 1_2 is formed via a metal sintering process so that the thermal protection member 530_2 can be attached to the lower surface of a buffer layer 520 (e.g., second base resin 521) without any adhesive member therebetween. In this embodiment, for example, the thermal protection member 530_2 may include a metal powder MP.

The thermal protection member 530_2 may be formed by disposing the metal powder MP on the lower surface of the buffer layer 520 and sintering the metal powder MP. The process of sintering the metal powder MP may be carried out using, for example, intense pulsed light.

With the above configuration, the panel bottom member 500_2 according to this embodiment requires no adhesive member between the thermal protection member 530_2 and the buffer layer 520, so that the thickness of the panel bottom member 500_2 can be effectively reduced.

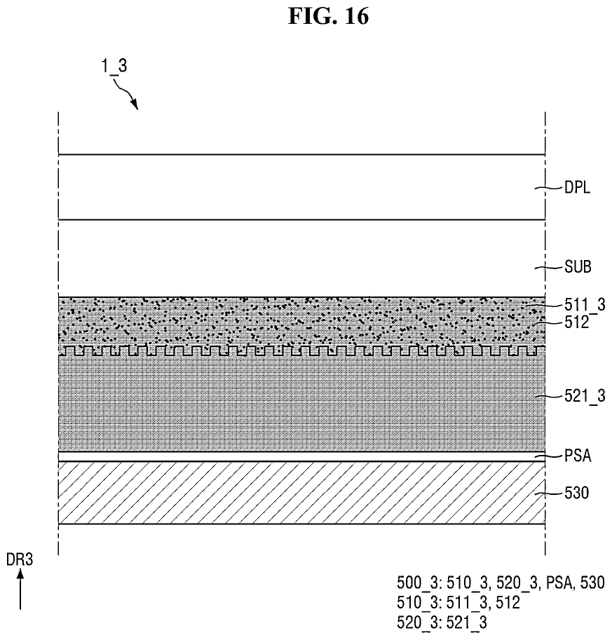

FIG. 16 is a cross-sectional view showing a structure of a panel bottom member of a display device according to yet another embodiment.

According to the embodiment of FIG. 16, a concave-convex pattern may be formed on a surfaces where the light-blocking layer 510_3 and the buffer layer 520_3 are in contact with each other in a panel bottom member 500_3 of a display device 1_3. The light-blocking layer 510_3 may include a first base resin 511_3 where a first convex-and-concave pattern is formed, and the buffer layer 520_3 may include a second base resin 521_3 where a second convex-and-concave pattern engaged with the first convex-and-concave pattern is formed.

The light-blocking layer 510_3 may include a first base resin 511_3 and light-blocking particles 512 dispersed in the first base resin 511_3. The light-blocking particles 512 are identical to those described above; and, therefore, the redundant descriptions will be omitted.

The first base resin 511_3 may be a solvent-free resin. Accordingly, the first base resin 511_3 is discharged via an inkjet printing process, so that the amount of the first base resin 511_3 can be adjusted depending on different areas and can be cured quickly, to form a first concave-convex pattern on the lower surface of the first base resin 511_3.

In some embodiments, the first base resin 511_3 may include a solvent-free thiol resin, an epoxy cation resin, or an amine resin. This may be to prevent deterioration of the surface curing reaction due to oxygen present in the atmosphere as the light-blocking layer 510_3 is formed in the atmosphere.

The buffer layer 520_3 may be formed of or include the second base resin 521_3. The second base resin 521_3 may be a solvent-free resin. Accordingly, the second base resin 521_3 is discharged via an inkjet printing process, so that the amount of the second base resin 521_3 can be adjusted depending on different areas and can be cured quickly, to form a second concave-convex pattern on the upper surface of the buffer layer 520_3.

In some embodiments, the second base resin 521_3 may include a solvent-free thiol resin, an epoxy cation resin, or an amine resin. This may be to prevent deterioration of the surface curing reaction due to oxygen present in the atmosphere as the buffer layer 520_3 is formed in the atmosphere.

With the above configuration, the light-blocking layer 510_3 and the buffer layer 520_3 are in contact with each other with the interface having the concavo-convex patterns, so that the adhesive force between the light-blocking layer 510_3 and the buffer layer 520_3 can be further enhanced.

Although the thermal protection member 530 is attached to the composite layer 540 via the adhesive member PSA in the embodiment shown in FIG. 16, it is to be understood that the thermal protection member 530_1 described above with reference to FIG. 14 and the thermal protection member 530_2 described above with reference to FIG. 15 may also be employed.

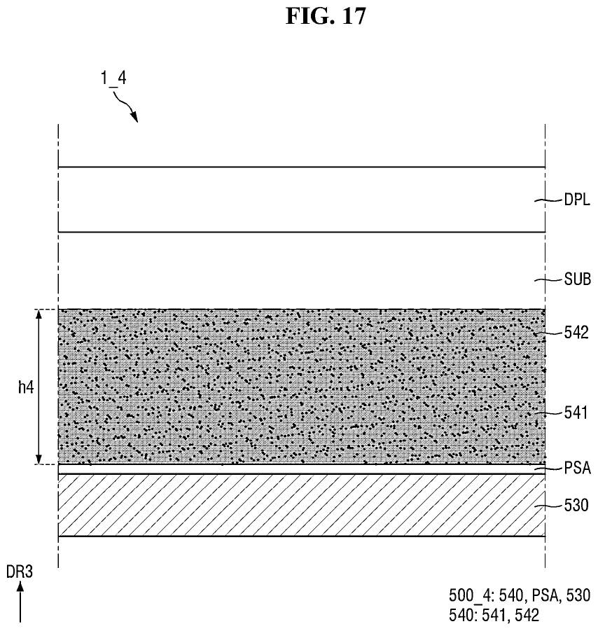

FIG. 17 is a cross-sectional view showing a structure of a panel bottom member of a display device according to yet another embodiment.

According to the embodiment of FIG. 17, a panel bottom member 500_4 of a display device 1_4 includes a composite layer 540 that blocks light and absorbs shock, and a thermal protection member 530 disposed thereunder. For example, the composite layer 540 of the panel bottom member 500_4 according to this embodiment may be implemented by incorporating the light-blocking layer 510 and the buffer layer 520 of the panel bottom member 500 of the display device 1 according to the embodiment of FIG. 6.

In some embodiments, the composite layer 540 may be in direct contact with the lower surface of the display substrate SUB, but the present disclosure is not limited thereto. For another example, when a material layer is disposed between the composite layer 540 and the display substrate SUB, the composite layer 540 may be in direct contact with the lower surface of the material layer. In the embodiment shown in FIG. 17, the composite layer 540 and the lower surface of the display substrate SUB may be in direct contact with each other.

The composite layer 540 may include a fourth base resin 541 and light-blocking particles 542 dispersed in the fourth base resin 541. The light-blocking particles 542 are substantially identical to the light-blocking particle 512 according to the embodiment of FIG. 6; and, therefore, the redundant descriptions will be omitted.

The fourth base resin 541 may be a solvent-free resin. When the composite layer 540 is made of a resin, the thickness should be approximately 100 μm or more in order to block light and absorb shock. Therefore, as described above, in order to form the composite layer 540 with a thickness of several micrometers (μm), the fourth base resin 541 should be a solvent-free type resin.

The fourth base resin 541 may have a glass transition temperature of −30° C. or less. If the glass transition temperature of the fourth base resin 541 is −30° C. or less, the impact resistance desirable for the composite layer 540 can be ensured. If the glass transition temperature of the fourth base resin 541 is higher than −30° C., the impact resistance desirable for the composite layer 540 may not be ensured. For example, if the glass transition temperature of the fourth base resin 541 is −42.9° C., the fourth base resin 541 may not be broken even though an iron ball is dropped from the height of 13 cm onto the fourth base resin 541.

In some embodiments, the fourth base resin 541 may include a solvent-free thiol resin, an epoxy cation resin, or an amine resin. This may be to prevent deterioration of the surface curing reaction due to oxygen present in the atmosphere as the composite layer 540 is formed in the atmosphere. A detailed description thereon will be made later.

In some embodiments, the thickness h4 of the composite layer 540 may be, but is not limited to, approximately 100 μm to 120 μm.

With the above configuration, the composite layer 540 can block light and absorb shock, thereby simplifying the fabricating process.

Although the thermal protection member 530 is attached to the composite layer 540 via the adhesive member PSA in the embodiment shown in FIG. 17, it is to be understood that the thermal protection member 530_1 described above with reference to FIG. 14 and the thermal protection member 530_2 described above with reference to FIG. 15 may also be employed.

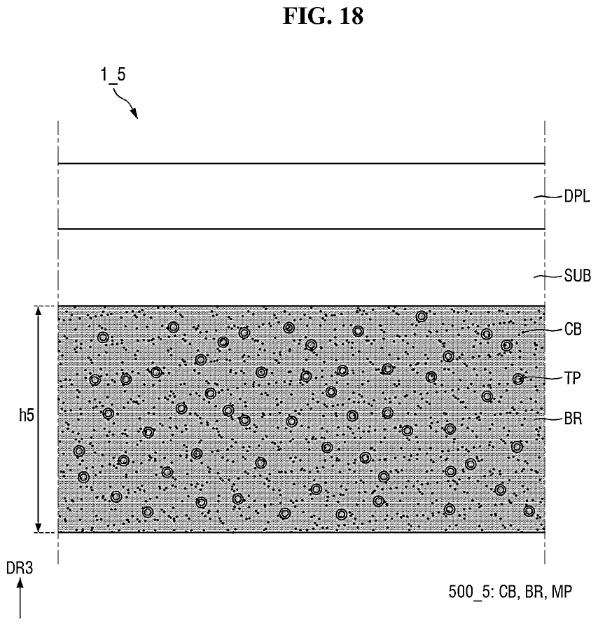

FIG. 18 is a cross-sectional view showing a structure of a panel bottom member of a display device according to yet another embodiment.

According to the embodiment of FIG. 18, a panel bottom member 500_5 of a display device 1_5 can block light, absorb shock, and protect against heat. For example, the panel bottom member 500_5 according to this embodiment may be implemented by incorporating the light-blocking layer 510, the buffer layer 520 and the thermal protection member 530 of the panel bottom member 500 of the display device 1 according to the embodiment of FIG. 6.

In some embodiments, the panel bottom member 500_5 may be in direct contact with the lower surface of the display substrate SUB, but the present disclosure is not limited thereto. For example, when a separate material layer is disposed between the panel bottom member 500_5 and the display substrate SUB, the panel bottom member 500_5 may be in direct contact with the lower surface of the material layer. In the embodiment shown in FIG. 18, the panel bottom member 500_5 and the lower surface of the display substrate SUB may be in direct contact with each other.

The panel bottom member 500_5 may include a base resin BR, light-blocking particles CB dispersed in the base resin BR, and thermal protection particles TP dispersed in the base resin BR.

The light-blocking particles CB are substantially identical to the light-blocking particle 512 described above with reference to FIG. 6, and the thermal protection particles TP are substantially identical to the nano-metal particles 532 described above with reference to FIG. 14; and, therefore, the redundant descriptions will be omitted.

The base resin BR may be a solvent-free resin. When the panel bottom member 500_5 is made of a resin, it is desirable to have a thickness of approximately 100 μm or more in order to block light, protect against heat and absorb external shock. Therefore, as described above, in order to form the panel bottom cover 500_5 with a thickness of several micrometers (μm), the base resin BR should be a solvent-free type resin.

The base resin BR may have a glass-transition temperature of −30° C. or less. If the glass-transition temperature of the base resin BR is −30° C. or less, the impact resistance desirable for the composite layer 540 can be ensured. If the glass-transition temperature of the base resin BR is higher than −30° C., the impact resistance desirable for the panel bottom member 500_5 may not be ensured. For example, if the glass transition temperature of the base resin BR is −42.9° C., the base resin BR may not be broken even though an iron ball is dropped from the height of 13 cm onto the base resin BR.

In some embodiments, the base resin BR may include a solvent-free thiol resin, an epoxy cation resin, or an amine resin. This may be to prevent deterioration of the surface curing reaction due to oxygen present in the atmosphere as the panel bottom cover 500_5 is formed in the atmosphere. A detailed description thereon will be made later.

In some embodiments, the thickness h5 of the panel bottom member 500_5 may be, but is not limited to, approximately 100 μm to 120 μm.

With the above configuration, the panel bottom member 500_5 can block light, protect against heat, and absorb shock, thereby simplifying the fabricating process.

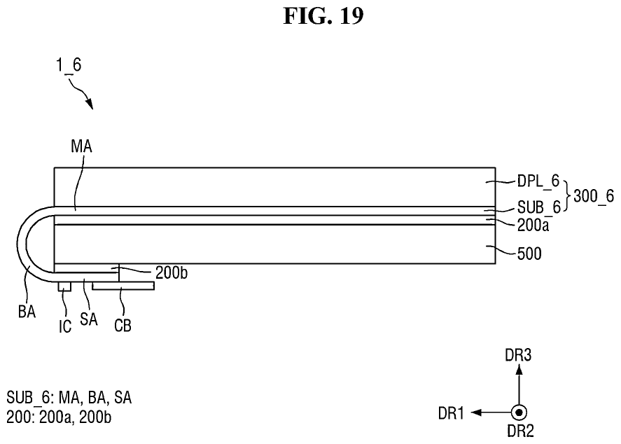

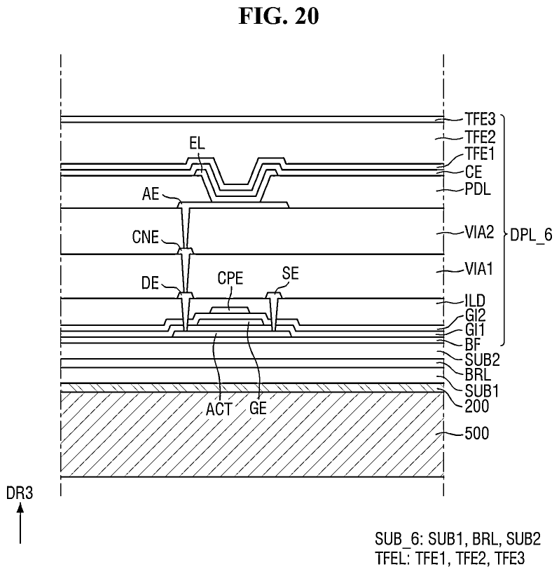

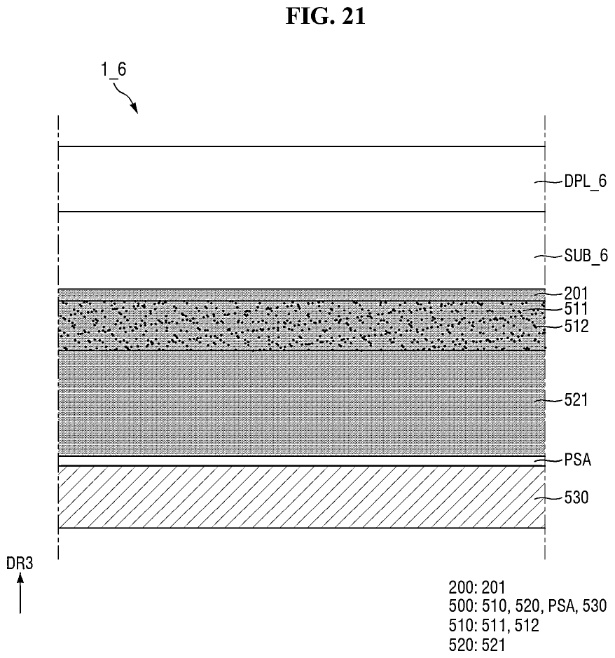

FIG. 19 is a cross-sectional view showing an arrangement of a display panel and a panel bottom member of a display device according to yet another embodiment. FIG. 20 is a cross-sectional view showing the stack structure of the display panel of the display device according to the embodiment of FIG. 19. FIG. 21 is a cross-sectional view showing the structure of the panel bottom member of the display device according to the embodiment of FIG. 19.

In the embodiment shown in FIGS. 19 to 21, a display panel 300_6 of a display device 1_6 according to this embodiment may have flexibility. For example, the display panel 300_6 may include a display substrate SUB_6 and a display element layer DPL_6 disposed thereon, which are flexible.

Initially, the arrangement of the display panel 300_6 and the panel bottom member 500 according to this embodiment will be described with reference to FIG. 19.

The display substrate SUB_6 of the display panel 300_6 according to this embodiment may include a main area MA in which the display element layer DPL_6 is disposed, a subsidiary area SA in which a driver circuit IC and a circuit board CB are mounted, and a bending area BA connecting the main area MA with the subsidiary area SA.

In addition, the panel bottom member 500 according to this embodiment may be extended only to the main area MA of the display substrate SUB_6.

As described above, since the display substrate SUB_6 has flexibility, the bending area BA may be bent in the opposite direction to the third direction DR3. Accordingly, the subsidiary area SA disposed at one end of the bending area BA may be disposed on the lower surface of the panel bottom member 500 disposed under the main area MA, and the bending area BA may surround the side surface of the panel bottom member 500 in the first direction DR1. As a result, the non-display area of the display device 1_6 can be reduced.

A lower film 200 for supporting rigidity of the display substrate SUB_6 may be disposed on the lower surface of the display substrate SUB_6. The lower film 200 may be in direct contact with the lower surface of the display substrate SUB_6 without any adhesive member. This is because the lower film 200 is made of a resin and is formed directly on the lower surface of the display substrate SUB_6.

The lower film 200 may include a first portion 200a supporting the main area MA of the display substrate SUB_6 and a second portion 200b supporting the subsidiary area SA. Since the lower film 200 is not disposed on the lower surface of the bending area BA, the bending area BA can be flexible.

Subsequently, the structure of the display element layer DPL_6 and the display substrate SUB_6 according to the embodiment will be described with reference to FIG. 20. The display element layer DPL_6 according to the embodiment is substantially identical to the display device 1 according to the above embodiment except that the former may further include a thin-film encapsulation layer TFEL. In addition, the display device according to this embodiment is substantially identical to the display device 1 according to the above embodiment except that the substrate SUB_6 is made up of multiple layers.

The substrate SUB_6 according to this embodiment can be curved, bent, folded, rolled, or stretched. The substrate SUB_6 may be made of, for example, an insulating material such as a polymer resin. Examples of the polymer material may include polyethersulphone (“PES”), polyacrylate (“PA”), polyacrylate (“PAR”), polyetherimide (“PEI”), polyethylene naphthalate (“PEN”), polyethylene terephthalate (“PET”), polyphenylene sulfide (“PPS”), polyallylate, polyimide (“PI”), polycarbonate (“PC”), cellulose triacetate (“CAT”), cellulose acetate propionate (“CAP”) or a combination thereof.

The substrate SUB_6 may include a first sub-substrate SUB1, a second sub-substrate SUB2, which are flexible, and a barrier layer BRL disposed between the first sub-substrate SUB1 and the second sub-substrate SUB2. Each of the first sub-substrate SUB1 and the second sub-substrate SUB2 may be a flexible substrate made of polyimide, etc. The barrier layer BRL may include silicon nitride, silicon oxide, silicon oxynitride, etc.

A variety of elements disposed on the substrate SUB_6 are substantially identical to a variety of elements of the display device 1 according to the embodiment described above with reference to FIG. 5; and, therefore, the redundant descriptions will be omitted.

The thin-film encapsulation layer TFEL is disposed on the common electrode CE. The thin-film encapsulation layer TFEL may include a first inorganic encapsulation film TFE1, an organic encapsulation film TFE2 and a second inorganic encapsulation film TFE3 stacked on one another in this order. Each of the first inorganic encapsulation film TFE1 and the second inorganic encapsulation film TFE3 may include silicon nitride, silicon oxide, or silicon oxynitride. The organic encapsulation film TFE2 may include an organic insulating material such as polyacrylate resin, epoxy resin, phenolic resin, polyamide resin, polyimide resin, unsaturated polyesters resin, polyphenylene ether resin, polyphenylene sulfide resin, and benzocyclobutene (“BCB”).

The first inorganic encapsulation layer TFE1 is disposed on the common electrode CE. The organic encapsulation film TFE2 is disposed on the first inorganic encapsulation film TFE1. The organic encapsulation layer TFE2 has a large thickness, and thus can provide a substantially flat surface over the underlying structures having different heights. The upper surface of the organic encapsulation film TFE2 may be flat, but the present disclosure is not limited thereto. The second inorganic encapsulation film TFE3 is disposed on the organic encapsulation film TFE2. Although not shown in the drawings, the first inorganic encapsulation film TFE1 and the second inorganic encapsulation film TFE3 may come in contact with each other in the non-display area or a part of the display area, to encapsulate the inner space.

According to this embodiment, the thin-film encapsulation layer TFEL can provide encapsulation on the behalf of the encapsulation substrate ESUB described above with reference to FIG. 5. Since the thin-film encapsulation layer TFEL is more flexible than the glass substrate, the display panel 300_6 employing it can be generally flexible.

Subsequently, a structure of the panel bottom member 500 and a structure of the lower film 200 of the display device 1_6 according to this embodiment will be described with reference to FIG. 21.

The lower film 200 according to this embodiment may be in direct contact with the lower surface of the display substrate SUB_6. The lower film 200 may include abase resin 201.

The base resin 201 may be a solvent-free resin. When the lower film 200 is made of a resin, the thickness should be approximately several micrometers (μm) or more in order to support the display substrate SUB_6. Therefore, as described above, in order to form the lower film 200 with a thickness of several micrometers (μm), the base resin 201 should be a solvent-free type resin.

In some embodiments, the base resin 201 may include a solvent-free thiol resin, an epoxy cation resin, or an amine resin. This may be to prevent deterioration of the surface curing reaction due to oxygen present in the atmosphere as the lower film 200 is formed in the atmosphere.

The panel bottom member 500 may be in direct contact with the lower surface of the lower film 200. For example, the upper surface of the light-blocking layer 510 of the panel bottom member 500 may be in direct contact with the lower surface of the lower film 200. The panel bottom member 500 according to this embodiment is substantially identical to the panel bottom member 500 described above with reference to FIG. 6; and, therefore, the redundant descriptions will be omitted.

With the above configuration, the display substrate SUB_6 and the lower film 200 can be attached together without any adhesive member therebetween, so that the thickness of the display device 1_6 can be effectively reduced.

It is to be understood that the panel bottom member 500_1 described above with reference to FIG. 14, the panel bottom member 500_2 described above with reference to FIG. 15, the panel bottom member 500_3 described above with reference to FIG. 16, the panel bottom member 500_4 described above with reference to FIG. 17 and the panel bottom member 500_5 described above with reference to FIG. 18 may be employed as the panel bottom cover 500 according to this embodiment.

In addition, although the lower film 200 forms the boundary with the panel bottom member 500 in the embodiment shown in FIG. 21, the present disclosure is not limited thereto. The lower film 200 may be formed integrally with at least one functional layer of the panel bottom member 500, similarly to that described above with reference to FIGS. 17 and 18.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A display device comprising:
a substrate comprising a first surface and a second surface opposite to the first surface;
a display element layer disposed on the first surface of the substrate; and
a panel bottom member disposed on the second surface of the substrate,
wherein the panel bottom member comprises:
a light-blocking layer comprising a first base resin and light-blocking particles dispersed in the first base resin;
a buffer layer comprising a second base resin; and
a thermal protection member comprising a thermal protection material,
wherein a profile of the light-blocking layer conforms to a profile of the buffer layer in a plan view, and
wherein a first surface of the light-blocking layer and a first surface of the buffer layer are in direct contact with each other.

2. The display device of claim 1, wherein a surface of the thermal protection member is in direct contact with a second surface of the buffer layer, and the second surface of the buffer layer is opposite to the first surface of the buffer layer.

3. The display device of claim 2, wherein the thermal protection member comprises: a third base resin; and nano-metal particles dispersed in the third base resin.

4. The display device of claim 3, wherein each of the first base resin, the second base resin and the third base resin is a solvent-free resin.

5. The display device of claim 4, wherein the nano-metal particles comprise copper (Cu), and wherein a diameter of each of the nano-metal particles is equal to or less than 500 nanometers (nm).

6. The display device of claim 1, wherein the thermal protection member is disposed on a second surface of the buffer layer, and the second surface of the buffer layer is opposite to the first surface of the buffer layer,
wherein an adhesive member is interposed between the second surface of the buffer layer and the thermal protection member.

7. The display device of claim 6, wherein the thermal protection member comprises copper (Cu), and
wherein a profile of the thermal protection member conforms to a profile of the buffer layer in the plan view.

8. The display device of claim 1, wherein the first surface of the light-blocking layer forms a first concave-convex pattern, and
wherein the first surface of the buffer layer forms a second concave-convex pattern engaged with the first concave-convex pattern.

9. The display device of claim 1, wherein the second surface of the substrate is in direct contact with a second surface of the light-blocking layer, and the second surface of the light-blocking layer is opposite to the first surface of the light-blocking layer.

10. The display device of claim 9, wherein the substrate comprises one of glass and quartz.

11. The display device of claim 1, further comprising:
a lower film disposed directly on the second surface of the substrate,
wherein a second surface of the light-blocking layer is in direct contact with the lower film, and the second surface of the light-blocking layer is opposite to the first surface of the light-blocking layer.

12. The display device of claim 11, wherein the substrate comprises polyimide.

13. A display device comprising:
a substrate comprising a first surface and a second surface opposite to the first surface;
a display element layer disposed on the first surface of the substrate; and
a panel bottom member disposed on the second surface of the substrate,
wherein the panel bottom member comprises:
a first base being a solvent-free resin;
light-blocking particles dispersed in the first base; and
a thermal protection material, and
wherein a profile of the panel bottom member conforms to a profile of the substrate in a plan view.

14. The display device of claim 13, wherein the first base includes one of a thiol resin, an epoxy cation resin, and an amine resin.

15. The display device of claim 14, wherein a thickness of the first base ranges from about 100 micrometers (μm) to about 120 μm.

16. The display device of claim 15, wherein the panel bottom member further comprises nano-metal particles dispersed in the first base,
wherein the light-blocking particles comprises carbon black, and
wherein the nano-metal particles comprise copper (Cu) having a diameter of 500 nm or less.

17. The display device of claim 14, further comprising:
a second base in direct contact with the first base,
wherein the second base comprises one of a thiol resin, an epoxy cation resin and an amine resin, and the resins are solvent-free resins.

18. The display device of claim 17, wherein a glass-transition temperature of the second base is −30 degrees in Celsius (° C.) or less.

19. The display device of claim 18, wherein a thickness of the first base is smaller than a thickness of the second base.

20. A method of fabricating a display device, the method comprising:
forming a display element layer on a first surface of a substrate;
applying a resin for a light-blocking layer on a second surface of the substrate opposite to the first surface;
forming the light-blocking layer by curing the resin for the light-blocking layer applied on the second surface;
applying a resin for a buffer layer directly on the light-blocking layer; and
forming the buffer layer by curing the resin for the buffer layer applied directly on the light-blocking layer.
